(19) United States
(12) Patent Application Publication
(10) Pub. No.: US 2017/0162417 A1
(43) Pub. Date: Jun. 8, 2017

(54) METHOD AND APPARATUS FOR CLAMPING AND DECLAMPING SUBSTRATES USING ELECTROSTATIC CHUCKS

(71) Applicant: Applied Materials, Inc., Santa Clara, CA (US)

(72) Inventors: Zheng John YE, Santa Clara, CA (US); Hiroji HANAWA, Sunnyvale, CA (US); Juan Carlos ROCHA-ALVAREZ, San Carlos, CA (US); Pramit MANNA, Sunnyvale, CA (US); Michael Wenyoung TSIANG, Fremont, CA (US); Allen KO, Fremont, CA (US); Wenjiao WANG, Sunnyvale, CA (US); Yongjing LIN, San Jose, CA (US); Prashant Kumar KULSHRESHTHA, San Jose, CA (US); Xinhai HAN, Santa Clara, CA (US); Bok Hoen KIM, San Jose, CA (US); Kwangduk Douglas LEE, Redwood City, CA (US); Karthik Thimmavajjula NARASIMHA, San Francisco, CA (US); Ziqing DUAN, Sunnyvale, CA (US); Deenesh PADHI, Sunnyvale, CA (US)

(21) Appl. No.: 15/370,682

(22) Filed: Dec. 6, 2016

Related U.S. Application Data
(63) Continuation of application No. 62/264,096, filed on Dec. 7, 2015.

(51) Int. Cl. H01L 21/683; C23C 16/505; C23C 16/458

(52) U.S. Cl. CPC H01L 21/6833; C23C 16/458; C23C 16/505; H01L 21/02274

(57) ABSTRACT

Techniques are disclosed for methods and apparatuses of an electrostatic chuck suitable for operating at high operating temperatures. In one example, a substrate support assembly is provided. The substrate support assembly includes a substantially disk-shaped ceramic body having an upper surface, a cylindrical sidewall, and a lower surface. The upper surface is configured to support a substrate thereon for processing the substrate in a vacuum processing chamber. The cylindrical sidewall defines an outer diameter of the ceramic body. The lower surface is disposed opposite the upper surface. An electrode is disposed in the ceramic body. A circuit is electrically connected to the electrode. The circuit includes a DC chucking circuit, a first RF drive circuit, and a second RF dive circuit. The DC chucking circuit, the first RF drive circuit and the second RF drive circuit are electrically coupled with the electrode.

### CROSS-REFERENCE TO RELATED APPLICATIONS

This application claims benefit of U.S. Provisional Application Ser. No. 62/264,096, filed Dec. 7, 2015 (Attorney Docket No. APPM/23518 USL), of which is incorporated by reference in its entirety.

### BACKGROUND

Field

Embodiments described herein generally relate to methods and apparatuses for forming semiconductor devices. More particularly, embodiments described herein generally relate to electrostatic chucks used in forming semiconductor devices.

Description of the Related Art

Reliably producing nanometer and smaller features is one of the key technology challenges for next generation very large scale integration (VLSI) and ultra large-scale integration (ULSI) of semiconductor devices. However, as the limits of circuit technology are pushed, the shrinking dimensions of VLSI and ULSI interconnect technology have placed additional demands on processing capabilities. Reliable formation of gate structures on the substrate is important to VLSI and ULSI success and to the continued effort to increase circuit density and quality of individual substrates and die.

Electrostatic chucks (ESC) operating on the principle of Johnsen-Rahbek (JR) effect force are commonly using in applications performed below 350 degrees Celsius. To drive down manufacturing costs, integrated chip (IC) manufactures demand higher throughput and better device yield and performance from every silicon substrate processed. Some fabrication techniques being explored for next generation devices under current development require processing at temperatures well above 350 degrees Celsius which may undesirably cause substrate bow, i.e., in excess of 200 um.

To prevent such excessive bowing, an increased clamping force is often required to flatten the substrate and remove bow during film deposition and device processing. However, conventional ESCs present on substrate support assemblies utilized to clamp the substrate experience charge leakage at the temperatures above 300 degrees Celsius, which degrade device yield and performance.

Film deposition processes performed without chucking the substrate show backside film deposition due to the bow of the substrates while processing, which substantially increase lithography tool downtime due to contamination. Bowing is even more of a problem when multiple film layers are formed on a substrate, i.e. staircase film stacks, used for gate stacks in memory devices. The ideal bow specification of the gate stack is neutral bow or neutral stress after a number of different material layers are deposited under high temperature. Typically, more layers utilized in the film stack tends to worsen the substrate bow. Therefore, current substrate support technology limits the number of layers which may be formed on the substrate when fabricating staircase film stacks.

Thus, there is a need for an improved substrate support suitable for use at processing temperatures above 300 degrees Celsius.

### SUMMARY

Methods and apparatuses are disclosed for an electrostatic chuck suitable for operating at high temperatures in a processing chamber.

In one example, a substrate support assembly is provided. The substrate support assembly includes a substantially disk-shaped ceramic body having an upper surface, a cylindrical sidewall, and a lower surface. The upper surface is configured to support a substrate thereon for processing the substrate in a vacuum processing chamber. The cylindrical sidewall defines an outer diameter of the ceramic body. The lower surface is disposed opposite the upper surface. An electrode is disposed in the ceramic body. A circuit is electrically connected to the electrode. The circuit includes a DC chucking circuit, a first RF drive circuit, and a second RF dive circuit. The DC chucking circuit, the first RF drive circuit and the second RF drive circuit are electrically coupled with the electrode.

In another example, a processing chamber is provided. The processing chamber includes a body having walls and a lid enclosing an interior volume. A substrate support assembly is disposed in the interior volume. The substrate support includes a substantially disk-shaped ceramic body having an upper surface, a cylindrical sidewall, and a lower surface. The upper surface is configured to support a substrate thereon for processing the substrate in a vacuum processing chamber. The cylindrical sidewall defines an outer diameter of the ceramic body. The lower surface is disposed opposite the upper surface. An electrode is disposed in the ceramic body. A circuit is electrically connected to the electrode. The circuit includes a DC chucking circuit, a first RF drive circuit, and a second RF dive circuit. The DC chucking circuit, the first RF drive circuit and the second RF drive circuit are electrically coupled with the electrode.

In yet another example, a method for constructing an ESC is provided. The method includes inserting a metal electrode inside a material of an ESC, wherein the metal electrode is of comparable size to a substrate support surface of the ESC and is substantially parallel to the substrate support surface; and connecting the metal electrode to a circuit through which an electric charge can be provided at the electrode, wherein the electrical charge from the electrode migrates to the substrate support surface of the ESC through the material and wherein the circuit is a closed loop electrical circuitry supplying a chucking voltage and charges to the metal electrode.

### BRIEF DESCRIPTION OF THE DRAWINGS

So that the manner in which the above recited features of the embodiments can be understood in detail, a more particular description of the embodiments, briefly summarized above, can be had by reference to embodiments, some of which are illustrated in the appended drawings. It is to be noted, however, that the appended drawings illustrate only examples of the embodiments and are therefore not to be considered limiting of its scope, for the disclosure can admit to other equally effective embodiments.

FIG. 1 is a cross section view of an illustrative vacuum processing chamber having a substrate support assembly in which embodiments of the disclosure may be practiced.

FIG. 2 illustrates one embodiment for a multiple frequency RF drive system.

FIG. 3 illustrates a first embodiment for the RF drive system circuitry.

FIG. 4 illustrates a second embodiment for the RF drive system circuitry.

FIG. 5A illustrates a chucking circuit formed through a substrate disposed on an ESC.

FIG. 5B illustrates a cucking circuit having an isolation transformer for the ESC.

FIG. 6 is a graph illustrating electrical properties of AlN dielectric materials.

FIG. 7 is an example of an analog notch filter using an operational amplifier to achieve 35 dB attenuation at a center frequency of 60 Hz.

FIG. 8 is a graph illustrating a comparison of a filtered and an unfiltered signal during an example deposition recipe with the ESC of FIG. 2.

FIGS. 9A-9C illustrate examples of implementations for an AlN surface pattern suitable for forming a dense contact with the substrate.

FIG. 10 is a graph illustrating how chucking force can be affected by several key parameters related to the geometry and material properties of the ESC.

FIG. 11 illustrates a method for constructing an ESC.

FIG. 12 illustrates a method for chucking a substrate with an ESC.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this disclosure and are therefore not to be considered limiting of its scope, for the disclosure may admit to other equally effective embodiments.

### DETAILED DESCRIPTION

The methods and apparatus disclosed herein related to a Johnsen-Rahbek electrostatic chuck (ESC) suitable for operating at high temperature ranges, or from about 100 degrees Celsius to about 700 degrees Celsius. For example, the ESC may be maintained at temperatures above 550 degrees Celsius. The ESC holds a substrate against a top surface of the ESC during semiconductor processing so that the substrate does not move and keeps consistent thermal and electrical contact with respect to the ESC. In plasma-enhanced chemical vapor deposition (PECVD) applications, the quality of processing operations from one substrate to the next relies on a consistent temperature and voltage throughout the processing of the substrates.

Incoming substrates to PECVD processing chambers often exhibit a certain degree of compressive bow or tensile bow prior to being clamped to the ESC. The high operating temperature of the processing chamber contributes to the bow. Post-processing, the bow of the substrate may be worse than the incoming bow due to the surface stresses induces by exposure to high temperatures during processing. Additionally, substrates with films having tensile stress may have edges that bow away from the substrate support during processing. Not chucking the substrate having tensile stressed filed during processing often undesirably allows thin film deposition on the back side of the substrate. In contrast, chucked substrates often tend to have less backside thin film deposition after processing.

The disclosed method and apparatus uses an ESC generate a sufficient clamping force to act upon the substrate so that the substrate becomes substantially flat, and is maintained substantially parallel with respect to the substrate supporting surface of the ESC, regardless of whether the substrate is flat, or exhibits a degree of bowing before processing. Thus, the ESC chucking of the substrate not only reduces the bow, but also improves consistency in the substrate temperature profile, thin film uniformity, and film properties.

The apparatus disclosed below is related an ESC configured to operate at a much higher operating temperature range, i.e., from 100 degrees Celsius to 700 degrees Celsius (operating temperature range) comprised to conventional ESCs. Most aspects related to the ESC such as ceramic materials selection and radio frequency (RF) filter design remain substantially the same regardless of whether there is, or is not, a RF drive from the heater side of the chamber, or regardless of what RF voltage and current is running on the RF mesh (bottom electrode) while a direct current (DC) chucking voltage is applied simultaneously to the same bottom electrode. It is recognized that in case of the level of the RF voltage and current present on the bottom electrode for chucking, either the RF voltage or current, or both, may be different or higher than those when the RF drive come from a top electrode instead of the bottom and heater side (i.e., from the substrate support assembly). As such, the protection circuitry may change accordingly in order to reach the same level of isolation. Namely, the input impedance for the particular operating frequency or frequencies may be higher in order to achieve the same level of the leakage RF voltage or current which correspond to those from top driven RF electrodes.

In one embodiment, the construction of a metal electrode of comparable size to the substrate is disposed inside the bulk pedestal material, and is built to be substantially parallel to the substrate which will be held against the pedestal top surface. Such electrode is configured to be connected to a DC power supply which will provide the source of electric charge, and from the electrode the stored charge may migrate to the top surface of the pedestal through the bulk material, such as aluminum nitride (AlN), of finite electrical conductivity. The surface charge will then induce an equal amount but of the opposite polarity charge on the bottom of the substrate where the Coulombic attraction forces between the opposite charges will effectively hold the substrate against the pedestal surface. The induced surface charges on the bottom of the substrate come from a contact connection between the top of the substrate to the other end of the DC power supply, usually through a common ground connection. Such a connection can be formed by striking and sustaining plasma between the substrate and the chamber ground walls which behaves as a conductive media to close the electric current loop. Releasing the substrate from the chuck is achieved by removing the voltage supplied to the electrode, together with the charges contained in the AlN pedestal, while keeping the plasma running until the charges on the substrate is drained. Optionally, a charge of opposite polarity may be applied to the electrode within the pedestal to more rapidly dissipate the attractive force.

In another embodiment, elements of a metal heater are embedded in the bulk dielectric material of the ESC so as to control the operating temperature of the chuck, and the temperature uniformity across a workpiece surface of the ESC. Such heater elements may be single or of multiple pieces of resistive heater filaments forming a specific pattern, leading to a desirable temperature distribution, or profile, across the workpiece surface of the ESC. A temperature profile for the workpiece surface may be maintained substantially consistent over a period of time, or may be changed to a different yet desirable temperature profile by dynamically adjusting the power to each of the heater elements.

In yet another embodiment, a network of electrical circuitry is implemented to protect the power supplies for the ESC and for the heater elements against AC and reactive RF voltage and current which may couple to the chucking electrode and the heater elements through the pedestal dielectric materials. Such coupling could be detrimental to the DC power supplies, AC power sources, and RF power sources which are not designed to handle the respective AC and RF load.

In yet another embodiment, pedestal bulk materials, surface contact area with or without specific pattern of contact, contact surface finish roughness, and the height of the contact islands, etc., are used to determine the desirable clamping force. An ESC configuration process may yield ESC designs best suited for one application requirement, or for multiple application requirements, depending upon the operating temperature, ESC voltage and current requirement, and time to chuck and release a substrate. For example, one configuration process may target at minimum chucking voltage using maximum contact area. Another example is to minimize the DC chucking current on the ESC power supply, where one may have lower current when using the dielectric materials of higher resistivity, and/or reducing the current going through the heater elements to ground by floating them against the ground. In cases where the heater elements are powered by alternating current (AC) lines of 60 Hz, an isolation transformer may be used between the heater elements and the AC lines. Yet another example of reducing the ESC current is to generate a layer of insulating materials on the pedestal surface which would cut off or significantly reduce the DC current leaking through the plasma to chamber ground. Such insulating layer can be either manufactured into the pedestal permanently, or generated in-situ of the chamber. The lower ESC voltage and current may benefit from small power supplies to facilitate system integration and cost reduction.

In yet another embodiment, a method may be to generated and executed where an optimum set of ESC operating parameters including temperature, ESC voltage, current, etc., can work with desirable process parameters such as gas chemistry, flow rates, pressure, RF power, etc., for the desired on-substrate film properties and throughput requirements. Such methods may include optimal timing control with respect to each of the parameters and between them. One example of the timing control is to strike and sustain helium plasma with RF power before turning on the ESC voltage where the substrate may be heated to a high temperature due to helium plasma bombardment, leading reduced surface stress before chucking occurs. Yet another example of the chucking method is to run different ESC voltages according to the recipe steps for optimal substrate results whereas, for example, a spike voltage may be used at the beginning of the chucking step to quickly chuck and flatten the bowing substrate while a lower ESC voltage is used for later process steps to maintain clamping force and to be ready for substrate release from a low chucking voltage.

The apparatus, and in particular, the ESC as described in detail below, may be particularly suited for generating advanced dielectric films such as those used for hard masks for lithography applications of a semiconductor manufacturing process. The ESC can be used to control high substrate bows during PECVD process to improve uniformity, repeatability, overlay error, chamber impedance, minimize backside deposition, etc.

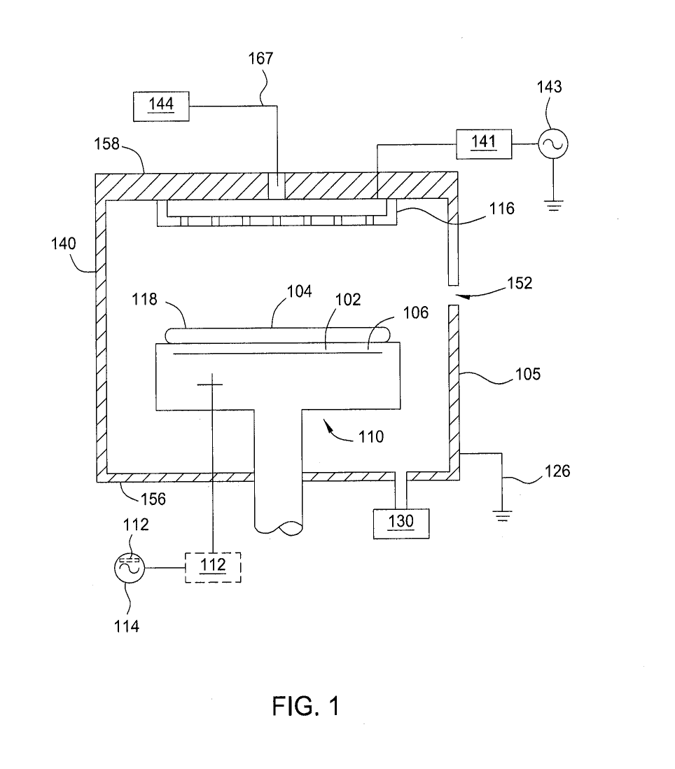

FIG. 1 is a schematic side view of one embodiment of a vacuum processing chamber 100 having a substrate support assembly 110 on which a substrate 118 is processed. The substrate support assembly 110 is an ESC suitably configured to provide chucking for reducing bow in the substrate and improving the temperature profile, thin film uniformity, and other film properties on the substrate. The processing chamber 100 may be a plasma-enhanced chemical vapor deposition (PECVD) processing chamber, a chemical vapor deposition (CVD) processing chamber, hot wire chemical vapor deposition (HWCVD) processing chamber, or other vacuum processing chamber suitable for processing substrates at elevated temperatures while under vacuum.

The processing chamber 100 includes a chamber body 105 having a top 158, chamber sidewalls 140 and a chamber bottom 156 which are coupled to a ground 126. The top 158, the chamber sidewalls 140 and the chamber bottom 156 define an interior processing region 150. The chamber sidewalls 140 may include a substrate transfer port 152 to facilitate transferring the substrate 118 into and out of the interior processing region 150 of the processing chamber 100. The substrate transfer port 152 may be coupled to a transfer chamber and/or other chambers of a substrate processing system.

The dimensions of the chamber body 105 and related components of the processing chamber 100 are not limited and generally are proportionally larger than the size of the substrate 118 to be processed therein. Examples of substrate sizes include 200 mm diameter, 250 mm diameter, 300 mm diameter and 450 mm diameter, among others.

A pumping device 130 is coupled to the bottom 156 of the processing chamber 100 to evacuate and control the pressure within the interior processing region 150 of the processing chamber 100. The pumping device 130 may be a conventional roughing pump, roots blower, turbo pump or other similar device that is adapted control the pressure in the interior processing region 150. In one example, the pressure level of the interior processing region 150 of the processing chamber 100 may be maintained at less than about 760 Torr.

A gas panel 144 supplies process and other gases through a gas line 167 into the interior processing region 150 of the chamber body 105. The gas panel 144 may be configured to provide one or more process gas sources, inert gases, non-reactive gases, and reactive gases, if desired. Examples of process gases that may be provided by the gas panel 144 include, but are not limited to, a silicon (Si) containing gases, carbon precursors and nitrogen containing gases. Examples of Si containing gases include Si-rich or Si-deficient nitride (SiₓN_{y}) and silicon oxide (SiO₂). Examples of carbon precursors include propylene, acetylene, ethylene, methane, hexane, hexane, isoprene, and butadiene, among others. Examples of Si containing gases include silane (SiH4), tetraethyl orthosilicate (TEOS). Examples of nitrogen and/or oxygen containing gases include pyridine, aliphatic amine, amines, nitriles, nitrous oxide, oxygen, TEOS, and ammonia, among others.

A showerhead 116 is disposed in the interior processing region 150 below the top 158 of the processing chamber 100 and is spaced above the substrate support assembly 110. As such, the showerhead 116 is directly above a top surface 104 of the substrate 118 when positioned on the substrate support assembly 110 for processing. One or more process gases provided from the gas panel 144 may supply reactive species through the showerhead 116 into the interior processing region 150.

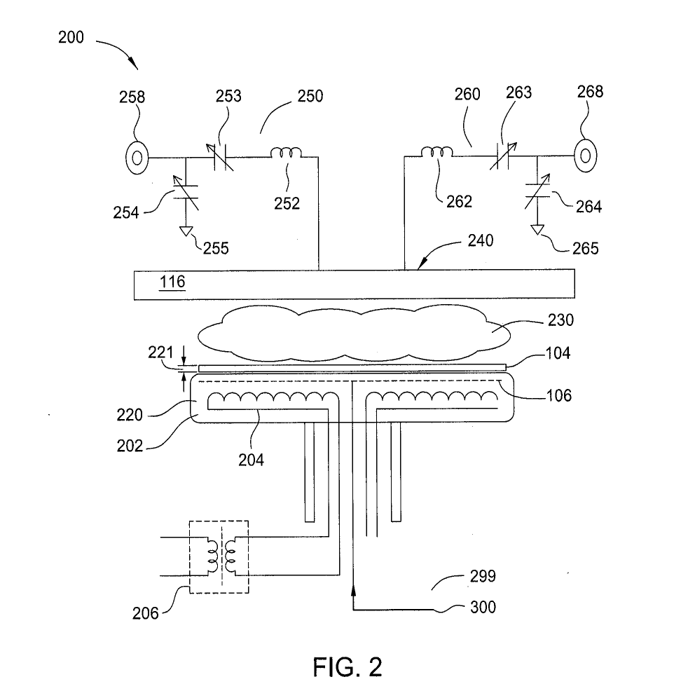

The showerhead 116 may also function as a top electrode for coupling power to gases within the interior processing region 150. The top electrode will be discussed further below with respect to FIG. 2. It is contemplated that power may be coupled to the gases within the interior processing region 150 utilizing other electrodes, coils or other RF applicators.

In the embodiment depicted in FIG. 1, a power supply 143 may be coupled through a match circuit 141 to the showerhead 116. The RF energy applied to the showerhead 116 from the power supply is inductively coupled to the process gases disposed in the interior processing region 150 to maintain a plasma in the processing chamber 100. Alternatively, or in addition to the power supply 143, power may be capacitively coupled to the process gases in the interior processing region 150 to maintain the plasma within the interior processing region 150. The operation of the power supply 143 may be controlled by a controller, (not shown), that also controls the operation of other components in the processing chamber 100.

As discussed above, the substrate support assembly 110 is disposed above the bottom 156 of the processing chamber 100 and holds the substrate 118 during deposition. The substrate support assembly 110 includes an electrostatic chuck (identified by reference numeral 220 in FIG. 2) for chucking the substrate 118 disposed thereon. The electrostatic chuck (ESC) 220 secures the substrate 118 to the substrate support assembly 110 during processing. The ESC 220 may be formed from a bulk dielectric material, for example a ceramic material, such as aluminum nitride (AlN), among other suitable materials. The ESC 220 uses the electro-static attraction to hold the substrate 118 to the substrate support assembly 110.

The ESC 220 includes a bottom electrode 106, that during operation, is connected to a power source 114 through an isolation transformer 112 disposed between the power source 114 and the bottom electrode 106. The isolation transformer 112 may be part of the power source 114 or separate from the power source 114, as shown by the dashed lines in FIG. 1. The power source 114 may apply a chucking voltage between about 0 Volts and about 5000 Volts to the bottom electrode 106. Alternately, the bottom electrode 106 may be driven with an RF voltage. The substrate voltage is controlled during processing in the range from about 0 V peak-to-peak up to about 5000 V peak-to-peak at an AC frequency, or at a mix of multiple AC and RF frequencies in the range of about 0 Hz to about 2000 MHz of a sinusoidal voltage waveform, or waveforms, where about 0 Hz represents a DC waveform of constant voltage that does not change with time, and about 0 V peak-to-peak represents the condition where the substrate potential is held at the ground potential, or is grounded.

The method for achieving the above mentioned RF voltage control on the substrate may be realized by applying a bias RF power of the appropriate frequency, or of a mix of multiple frequencies, to the substrate pedestal, i.e., ESC 220, through an RF generator and matching network which includes several measurement and feedback control elements based on the RF voltage, current, and power respectively, at one or multiple locations inside or outside of the RF drive network. Some of these measurements are either physically or electrically close to the substrate so as to reflect instantaneous RF voltage, current, and power variation on the substrate. A measurement that is electrically close to the substrate refers to one that is not physically close to the substrate, but at a location where the respective voltage, current and power are either substantially close to, or after applying the appropriate corrections based on the location information, would approach those made at the substrate. In case of RF voltage and current measurements, they are vectors that have their respective magnitude and phase components where the difference between their phases determines the real power loss where both voltage and current measurements are made. A feedback or feedforward control mechanism can be implemented against any one, or multiple measurements of the voltage, the current, or the real power loss, to achieve desirable thin film deposition rate, uniformity, stress, and other film properties of choice. It is the intention of the disclosure to teach the principle of operation for the ESC 220 as well as fundamental technical details in implementing through several examples of design and development.

The ESC 220 may have a multiple frequency RF drive system. The multiple frequency RF drive system will now be discussed with respect to FIG. 2. FIG. 2 illustrates one embodiment for a multiple frequency RF drive system 200. The ESC 220 is configured to operate at a temperature ranging between from about 100 degrees Celsius to about 700 degrees Celsius. The ESC 220 is shown having a substrate 118 thereon and disposed below the showerhead 116.

Although an implementation of the ESC 220 where the heater 204 is actively driven by RF power of any or multiple frequencies is described below, such RF drive scenarios do not change the very principle of chucking the ESC 220 which remain the same under high temperatures whether there is, or is not, active RF power driven from the heater side of the chamber.

A top electrode 240 may be coupled with the showerhead 116. The top electrode may have a first top circuit 260 coupled thereto. Optionally, the top electrode may a second top circuit 250 coupled thereto. The first top circuit 260, and optionally the second top circuit 250, provides RF energy to drive the top electrode 240 for maintaining a plasma 230. The plasma 230 is formed from appropriate gases configured to deposit multiple film layers on the substrate 118 disposed on the ESC 220.

In a first embodiment depicted in FIG. 2, the first top circuit 260 and the second top circuit 250 may be substantially similar. The first top circuit 260 may have a RF generator 268, a first inductor 262 and a first capacitor 263 coupled to the top electrode 240. A ground 265 may be coupled through a second capacitor 264 to the RF generator 268. In one embodiment, the RF generator 268 supplies RF voltage and current at about 27 MHz to the top electrode 240. The second top circuit 250 may have a RF generator 258, a third inductor 252 and a third capacitor 253 coupled to the top electrode 240. A second ground 255 may be coupled through a fourth capacitor 254 to the RF generator 258. The RF generator 258 supplies RF voltage and current at about 400 KHz to the top electrode 240.

In a second embodiment, the second top circuit 250 and the first top circuit 260 are dissimilar. The second top circuit 250 has the second ground 255 coupled through the fourth capacitor 254 and the third inductor 252. However, the second top circuit 250 is does not include the RF generator 258 or third capacitor 253.

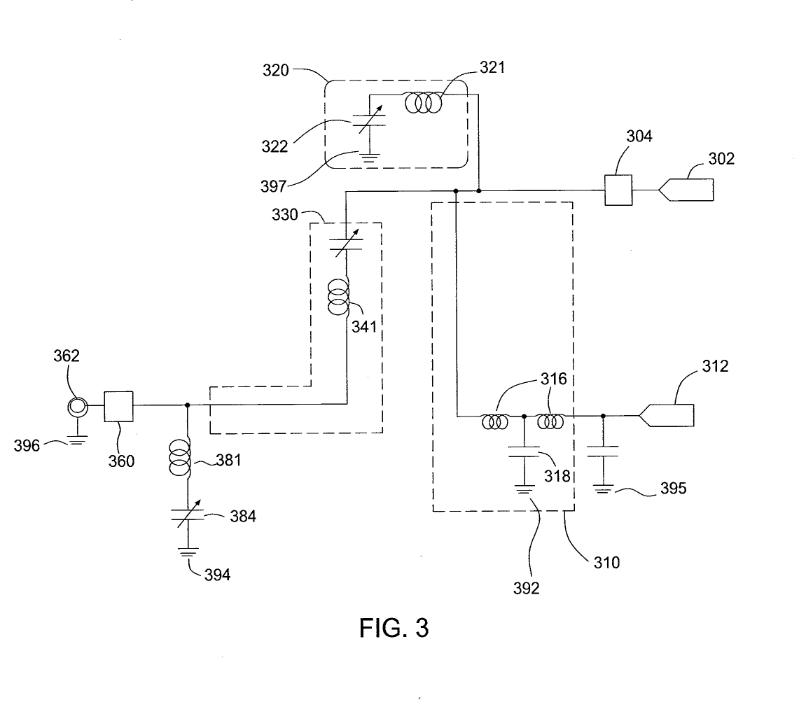

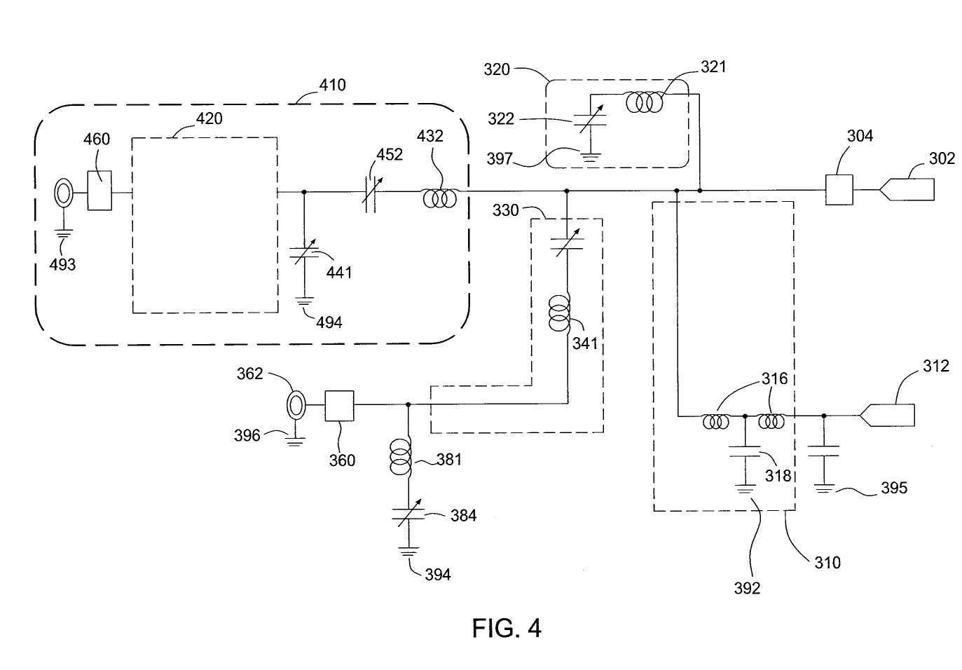

The ESC 220 may have a dielectric body 202. Heaters 204 may be disposed in the dielectric body 202. The embedded heaters 204 may be coupled to a heater power circuit. The bottom electrode 106 is embedded in the dielectric body 202 and may be coupled to a RF port 299 for attaching to RF drive system circuitry 300 (discussed in detail with respect to FIGS. 3 and 4). The dielectric body 202 may be formed from a ceramic material or other suitable insulating material. For example, the dielectric body 202 may be formed from aluminum nitride (AlN). The ESC 220 has a high breakdown voltage while substantially reducing the voltage leakage during operation at temperatures exceeding about 300 degrees Celsius. The ESC 220 may include a dielectric films coating and/or seasoning which inhibits charge leakage from the ESC 220 when operated at temperatures exceeding about 300 degrees Celsius. Suitable dielectric films have a dielectric constant about 3 to 12. The dielectric constant may be tuned to control charge trapping and for modifying the clamping/chucking force at elevated temperatures. In one embodiment, the dielectric body 202 may have a volume resistivity is in the range of about 1E7 Ohm-cm to about 1E9 Ohm-cm, and relative dielectric constant of about 8 to about 10, in the specified ESC 220 operating temperature range. The high voltage ESC 220 is suited for applications for forming gate stack films with multiple, alternative layers of oxide and poly-silicon films, and with multiple, alternative layers of oxide and nitride films, among other applications.

The apparatus as described below may be used to generate multiple layer film depositions, typically referred to as staircase films that are used for gate stack of dielectric materials for memory devices. It is recognized that due to the accumulated stress each layer is deposited on the previous layer, or layers, a silicon substrate may become bowed during the process or at the end of the process leading to a failure to meet with the required bow specification. The ideal bow specification of the gate stack is neutral bow or neutral stress after a number of alternative layers are deposited under high temperature. For example, it is difficult for a 60-layer gate stack process to achieve a neutral stress because the higher number of layers generally worsens the substrate bow. As such, deposition apparatus which employs the ESC 220 as disclosed in this invention helps to extend the number of layers one can process with controlled substrate bow or stress at the end of the process.

Although the below implementation of the ESC 220 has a heater that is actively driven by RF power of any frequency, different RF drive scenarios at high temperatures are contemplated including active RF power driven from the heater side of the processing chamber.

Referring to FIG. 3, FIG. 3 illustrates a first embodiment for the RF drive system circuitry 300. The RF drive system circuitry 300 driving the ESC 220 uses about 27 MHz of source RF frequency and about 2 MHz of bias RF frequency and their respective RF impedance load located at the opposite side of the driving electrode.

The RF drive system circuitry 300 shows an example implementation of a dual frequency RF drive network that provides the RF power to the ESC 220 where the RF out port 302 is connected to the RF port 299 feeding the bottom electrode 106 in the ESC 220. The RF drive system circuitry 300 includes a plurality of sub-circuits. The RF drive system circuitry 300 may include a DC filter circuit 310, an RF impedance matching network 330, and a RF load circuit 320. The RF drive system circuitry 300 additionally has a DC source 312, a first RF drive 362, and one or more voltage and current sensors (VI sensors) 304, 360. The sub-circuits 310, 320, 330 are connected in parallel fashion providing different functions which include (a), the chucking voltage that is supplied to the ESC 220 through a DC filter circuit 310, (b) an RF load comprised of a LC series resonance circuit to provide a particular load impedance with respect to the source RF drive frequency F3 through RF load circuit 320, if any, (c), an RF impedance matching network 330 providing bias RF drive frequency F2, and (d), an RF impedance matching network 410 (FIG. 4) for the bias RF drive frequency F1.

The RF drive system circuitry 300 additionally has a plurality of grounds 392, 394, 395, 396, 397 which may be at a common voltage. The grounds 392, 394, 397 may each have a respective capacitor 318, 384, 322 associated therewith.

The DC filter circuit 310 may electrically isolate the DC source 301 from the remainder of the RF drive system circuitry 300. The DC filter circuit 310 may have a plurality of inductors 316. In one embodiment, the DC filter circuit 310 may have 7 or more inductors 316 arranged in series or parallel. The DC filter circuit 310 also has one or more grounds 392 as well as respective capacitors 318. The DC filter circuit 310 may be used to protect the DC chucking circuitry against possible incoming RF voltage and current at any involved RF drive frequency, or frequencies.

The RF impedance matching network 330 may have an inductor unit 340. The inductor unit may have one or more inductors and be capacitively connected to ground 393 and an RF drive 362. For example, the inductor unit 340 may have two inductors arranged in series or parallel to one another. The RF impedance matching network 330 may additionally have one or more capacitors or variable capacitors. The RF drive 362 may operate at 2 MHz or other suitable frequency. The RF drive 362 may pulsed or wave driven.

FIG. 4 illustrates an optional second embodiment for the RF drive system circuitry 400. FIG. 4 includes the plurality of sub circuits 310, 320, 330 present in FIG. 3. FIG. 4 additionally includes an impedance matching circuit 410 providing bias RF drive frequency F1. The impedance matching circuit 410 includes an RF drive 493 attached to a ground. The RF drive 493 may operate at about 13.56 MHz for providing RF drive frequency F1. A VI sensor 460 may be disposed between the RF drive 493 and a high pass filter 420. The impedance matching circuit 410 may additionally have one or more capacitors 441, 452 and a plurality of grounds 494. The RF drive frequency F1 may have a pass through inductor 432 leaving the impedance matching circuit 410.

The high pass filter 420 may include a plurality of capacitors and inductors. The high pass filter 420 may additionally have a ground for each respective inductor. The high-pass filter passes the RF drive frequency F1 having a frequency higher than a cutoff frequency and attenuates those frequencies lower than the cutoff frequency.

The RF Network depicted in FIGS. 3 and 4 will now be discussed together. The electrical circuitry illustrated in FIGS. 3 and 4 may be implemented to protect the power supplies for the ESC and for the heater elements against AC and reactive RF voltage and current which may couple to the chucking electrode and the heater elements through the pedestal dielectric materials. Such coupling could be detrimental to the DC power supplies or AC power sources which are not designed to handle the respective AC and RF load.

Multiple RF voltage and current sensors (VI sensors 304 460, 360) are embedded into the network at the RF drive input side for F1 and F2, and one at RF output side of the network capable of providing the voltage, current, and their phase difference information at both drive frequency of F1 and F2 to a control unit for feed-back and feed-forward control in real time. One example of such feedback control is to hold the voltage at constant during the deposition process while another example is to hold the current at constant, yet another example is to hold the real power loss at constant, by dynamically adjusting the built-in tuning elements in the matching networks, shown as the variable capacitors in FIGS. 3 and 4. The real RF power loss is represented by the per cycle average of the V(t)*I(t) product at each respective frequency, and is also the coupled RF power at the location of the V(t) and I(t) measurement, where V(t) and I(t) are the time domain signal of the RF voltage and current, respectively. Another, equivalent way to measure the coupled power is V*I*cos(φ) where V and I are the RMS, or root mean square values of V(t) and I(t), and φ is the phase difference between V(t) and I(t).

The above mentioned feedback and feed-forward control method is not limited to the built-in lumped circuit elements such as variable capacitors or variable inductors in the matching networks, but also includes other circuits for changing the operating frequency F1 and F2, respectively. It is noticed that change of frequency is achieved electrically in the RF generators whereas changing of capacitance and inductance value is achieved mechanically through step motors attached to those tuning elements. It is advantageous in terms of time or faster to reach the required impedance for frequency tune as compared to the mechanical tuning. In FIG. 4, the variable capacitor acts as a mechanical tuning element working together with a frequency tune RF generator for the F1 matching network, and another one for the F2 matching network. It is recognized that zero, one, two, or more mechanical tuning elements can be used together with frequency tuning to drive the ESC 220 at the required voltage, current, and RF power coupled to the plasma.

In another embodiment, the RF load is designed as a LC series resonant circuit which produces a zero or minimal RF impedance at the source RF drive frequency of F3. This is the frequency which drives the showerhead or the RF hot gas box and face plate stack (i.e., top electrode) on the opposite side of the substrate pedestal, conforming part of the capacitively coupled plasma reactor. The function of such load impedance tune circuit is to provide a favorable path for the RF current so that most, or all of the RF current at F3 frequency would go through the pedestal while minimal, or no current would go to the wall of the plasma reactor chamber. The load impedance described herein can be dynamically controlled such that neither zero nor all, but a specified amount of the RF current at a prescribed frequency will go through the substrate pedestal for the advantageous control of the film deposition rate, uniformity, and film properties including but not limited to the refractive indexes and film stress level. It is recognized that the source RF drive frequency F3 be not the same as any of the bias RF drive frequency F1 and F2, since if any of the F1 or F2 is substantially close to F3, than the bias RF power at F1 and F2 may be terminated at the load such that no power can be delivered to the substrate pedestal down-stream to the load impedance.

It is possible to not use any bias RF power as shown in FIG. 4 at frequency F1 from impedance matching circuit 410 and F2 together with the ESC 220, leading to an RF configuration where the only RF power comes from the showerhead or the gas box and face plate stack (i.e., top electrode) at the single frequency F3, i.e., the first top circuit 260, or at multiple RF frequencies of F3 and F4, i.e., the second top circuit 250, etc. It is recognized that F3 can be at a high RF or VHF frequency such as about 13.56 MHz, about 27 MHz, about 40 MHz, about 60 MHz, so on and so forth to cover all of the industrial frequency band approved by FCC for commercial applications, and F4 may be a frequency significantly lower than F3, for example, at about 2 MHz or about 400 kHz. It is recognized that such frequency configuration is advantageous in independently controlling the thin film growth process in that the high frequency F3 may be responsible primarily to drive the high density of the plasma while the lower frequency F4 is responsible primarily to control the ion energy impinging on the substrate during the film growth so as to control the film quality parameters including the stress and refractive indexes.

It is further the intention to the current release to use the above described source and bias RF drive network with the ESC 220 in a fashion that one or several of the RF drive power be not a continuous wave (CW) signal, but a pulsed one where its amplitude can be modulated by a square wave of specified frequency and duty cycle, for example, at about 10 kHz and about 50% duty cycle or any other pulsing frequency and duty cycle that are advantageous to the film growth process in terms of deposition rate and film properties. One example implementation is that the bias power (F2) is pulsed while source power (F3) is a continuous wave drive. The opposite configuration where the source power is pulsed but the bias power is continuous wave is also covered under the principle of the current invention with regards to the ESC 220. In one particular example, both the source and the bias RF power may be run in a pulsing mode where their frequencies are the same and their phase relations may be one that isn't in phase or at a certain degree (90/180) out of phase, i.e., random or not synchronized, or is one that is consistent or synchronized. This configuration is referred to as synchronized pulsing hereinafter. Whether for the synchronized or unsynchronized pulsing, it is recognized that there can be simultaneously another frequency, or multiple frequencies superimposed either actively driven from the source side or actively driven from the substrate pedestal, or the bias side.

As shown in FIG. 4, the impedance matching circuit 410 consists of multiple inductive elements followed by several cascaded stages of π type low pass filters comprised of shunt capacitors and bridging inductors between the filters. It is further recognized that the bridging inductor can be replaced by a parallel resonant circuit of an inductor and a capacitor to achieve a high impedance at a particular resonant frequency such as F1 or F2. Multiple such π type low pass filters at specified high impedance at designed frequencies can be cascaded to achieve high impedance at all operating frequencies including their respective harmonics frequencies. Not only that the filter network would appear to the RF matching circuit as high impedance for all operating frequencies, or exhibiting high scattering parameter of S11, but also they attenuate RF signals at these frequencies significantly such that the DC chucking power supply does not become a RF power load at any of these frequencies, exhibiting high scattering parameter S21. Sufficient attenuation, for example, at greater than 30 dB, is advantageous because most of the commercially available DC power supplies are not designed to serve as a load at any of the RF frequencies mentioned herein. Additionally, a sufficiently high impedance (S11) for the filter network of, for example, greater than 7.5 kΩ in magnitude at each of the RF frequencies, is advantageous because such high input impedance will provide substantially zero or minimal current be drawn from the matching circuitry such that the DC chucking circuit for the ESC 220 would not interfere with the RF drive functionality and desirable tuning functionality.

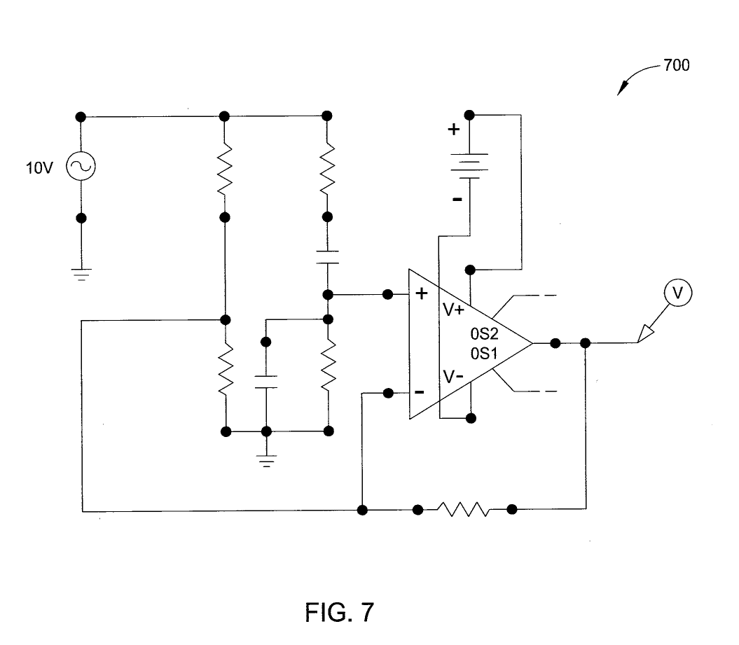

It is a further function of the current implementation of the filtering network that the previously described functionality be achieved at the power line frequency of about 50 to about 60 Hz, and including their harmonic frequencies of up to several kilo Hertz, and further up to tens of kilo Hertz range which covers a frequency band of commercial switching power supply switching frequencies. The reason for such functionality is to filter out any signals at such low frequencies which may reach and be detrimental to the DC chucking power supply or interfere with the functionality including the voltage and current regulation mechanism. One example of implementing such line frequency filter is to use a notch filter (such a notch filter is shown in FIG. 7), or a band-reject filter of several cascaded notch filters network to reject the any line frequency in particular, or to reject a wide band of noise frequencies including the described harmonics of the line frequencies.

RF filters circuitry with high input impedance to protect the ESC power supply and the AC power lines for heaters reduce the RF voltage and current going into the load it protects, and the circuit configuration may depend on the operating frequency. For example, at about 13.56 MHz, a LC parallel resonant circuit presents to the high voltage side as a high impedance circuit and thus acts as an open circuit for the RF frequency, ideally, but as pass through for other frequencies and for DC current. In case there are multiple RF frequencies involved, multiple filter stages can be used to satisfy a minimum RF impedance requirement at each of the operating frequency.

An RF filter circuitry may have multiple stages to satisfy the impedance requirement for all operating frequencies. In one embodiment the filter has a capacitor in parallel with an inductor. There may be specific filter requirement related to ESC 220 operating near the high end of the temperature regime. As discussed supra, the resistivity of the bulk dielectric materials becomes much lower than at high temperature which may increase coupling between the embedded chucking electrodes to the heater elements, as they are physically close. This means that lower frequency signals that exhibit primarily in the AC line side of the heater circuitry may couple to the chucking electrode and affect the chucking voltage. Example of the lower frequency signals are the line frequency at about 50 Hz or about 60 Hz. In case of switching on and off of the line frequency at a certain duty cycle to control the heater power and pedestal temperature, switching frequency can be several kHz range.

In a signal measured on the chucking electrode containing AC line as a result of coupling through the ESC bulk dielectric materials having an RMS value of the AC line signal of about 208 V, with a significant portion of the line voltage coupling to the chucking electrode, the DC ESC power supply will act as a load to the noise which may not be desirable since most of the DC power supplies commercially available are not designed to take AC load. The AC coupling problem may not be as severe at lower temperatures where the resistivity of the bulk dielectric materials is much higher. Incorporating additional AC line filters such as the one discussed above can reduce low frequency noise coupling to the chucking electrode and protect the ESC supply.

Implementation of multiple RF frequency and lower frequency filters may be necessary whether the filters are in series, in parallel, or in any combination, on each circuit branch as needed. In the circuitry illustrated above, one 13.56 MHz high impedance filter in series with a 27 MHz high impedance filter may be inserted between each of the connection line made to the embedded heater elements, whereas one additional low frequency EMI filter in series with the RF filters may be inserted between the embedded ESC electrode and the ESC power supply.

Various filter topologies may be used. For instance, the filter input impedance values, bandwidth, cut-off frequencies, frequency response curves, and the degree of attenuation, etc., may be selectable in any or all appropriate combinations. Such filter may reside in any appropriate location with respect to the ESC itself, regardless of whether inside, or outside of a chamber environment, close by, or remotely and apart from the sources which they are designed to protect upon.

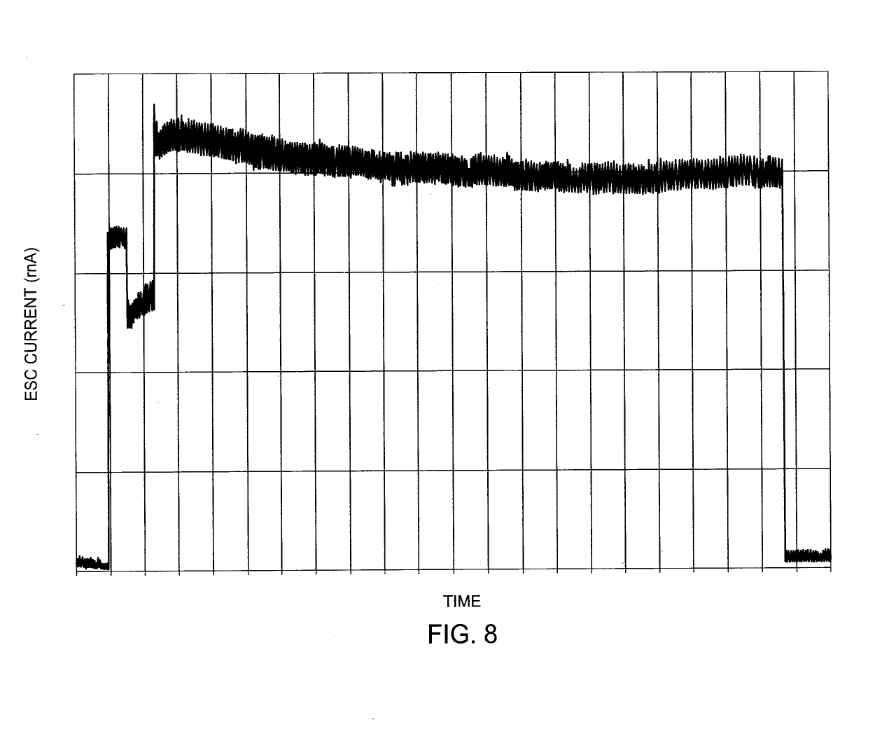

FIG. 7 is an example of an analog notch filter 700 using an operational amplifier to achieve 35 dB attenuation at the center frequency of 60 Hz. When the analog notch filter 700 is used together with another cascaded stage of a similar notch filter at 120 Hz, a general attenuation of nearly 20 dB can be achieved within a frequency band of 60 to 120 Hz range. In the implementation of notch filter shown in FIG. 4, an analog circuit for an operational amplifier 400 is employed. Such operational amplifiers 400 or their equivalent parts may be formed as a single chip integrated circuit package which houses multiple individual operational amplifier units. A compact design may be achieved by using such integrated operational amplifier chips for a band reject filter. FIG. 8 is a graph illustrating a comparison of a filtered and an unfiltered signal during an example deposition recipe with the ESC 220 shown in FIG. 2.

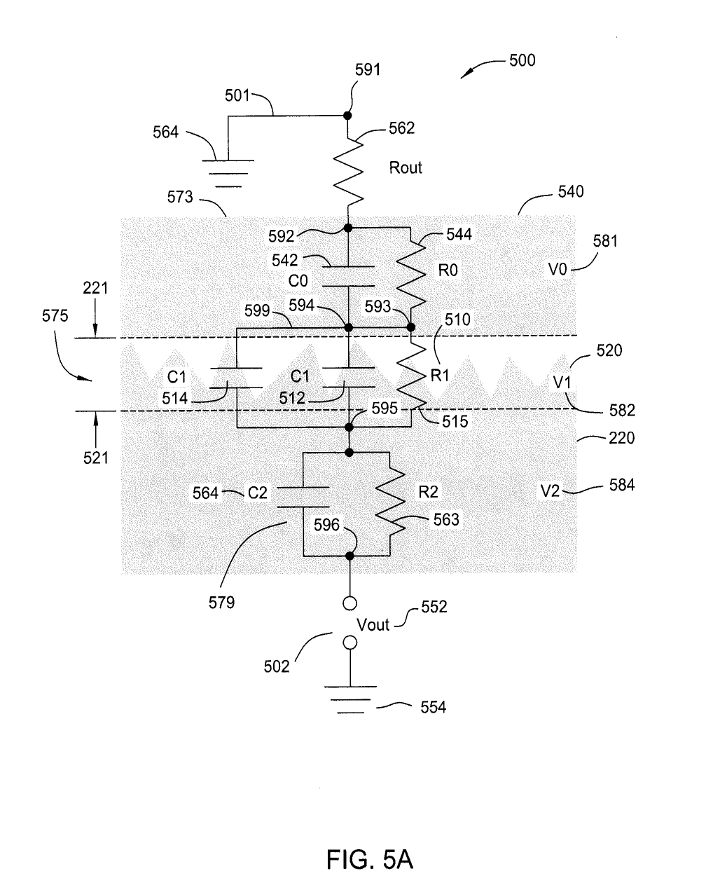

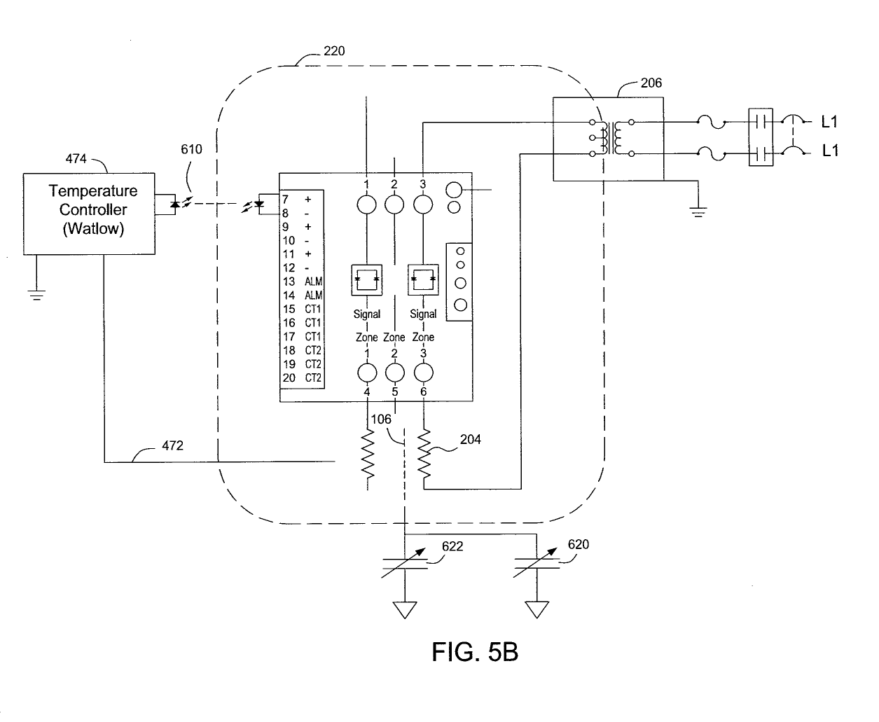

The use of Johnsen-Rahbek (JR) effect in an ESC at the specified high operating temperature regime, i.e., temperatures up to 700° Celsius, where the bulk dielectric material of the ESC 220 is aluminum nitride (AlN) whose volume resistivity is in the range of 1E7 to 1E10 Ohm-cm, and relative dielectric constant of 8 to 10 range will now be discussed with respect to FIG. 5A. The mechanical properties of the materials include its density and thermal conductivity, etc. are specified in the tables provided below.

FIG. 5A illustrates a chucking circuit 500 formed through a substrate 540 disposed on an ESC 220. In the chucking circuit 500, the substrate 540 formed from Si is in a partial contact with an ESC surface 520 forming the contact gap 221 which forms a (contact gap) capacitor 512. The geometry, gap height 521, effective contact area, surface roughness, and the resistivity of the AlN material as well as the substrate all contribute to the chucking circuit 500.

The chucking circuit 500 will now be described through a plurality of nodes. At a first end 501, a resistor out may be connected to a ground 504 through a first node 591 and connected to a second node 592. At a second end 502, an ESC supply voltage 552 may be disposed between a ground 554 and a sixth node. A plurality of sub-circuits may contribute to the chucking circuit 500. For example, a substrate circuit 573, a gap circuit 575 and a support circuit 574 may be disposed between the second node 592 at the first end and the sixth node 596 at the second end 502 of the chucking circuit 500.

The substrate circuit 573 is formed between the second node 592 and a virtual node 599. A third node 593 and a fourth node 594 may be viewed electrically in tandem as the virtual node 599 for purpose of describing the chucking circuit 500. A first resistor 544 is disposed between the second node 592 of the chucking circuit 500 and the third node 593 of the chucking circuit 500. A first capacitor 541 may be placed in parallel to the first resistor 544 and disposed between the second node 592 and the fourth node 594. The substrate circuit 573 between the second node 592 and the third and fourth node 593, 594, i.e., the first resistor 544 and first capacitor 542, is disposed in the substrate and may have a first voltage 581 thereacross.

The gap circuit 575 is formed between the virtual node 599 and a fifth node 595. The gap circuit 575 has a second capacitor 514, a third capacitor 512 and a second resistor 515 all in parallel between the virtual node 599 and the fifth node 595. A gap voltage 582 may be measure between the virtual node 599 and the fifth node 595.

The support circuit 574 may be formed between the fifth node 595 and the sixth node 596. The support circuit 5754 has a fourth capacitor 564 and a third resistor 563. The fourth capacitor 564 and the third resistor 563 are in parallel between the fifth node 595 and the sixth node 596. A support voltage 584 may be measured between the fifth node 595 and the sixth node 596.

The charge and the distribution of the charge upon the contact gap capacitor, i.e., the second capacitor 514 and the third capacitor 512, is influenced by the chucking circuit 500 such that a significant portion of an support voltage 584 will be applied to the contact gap 221 which effectively generates the chucking force. The time for charging and discharging the contact gap capacitor also determines the time to completely chuck the substrate 540, and subsequent release the substrate 540 from the ESC 220. The ESC power supply current (supplied at ESC supply voltage 552) is configured to maintain a constant chucking voltage during the entire processing of the substrate 540, or at specific steps of the processing recipe as needed.

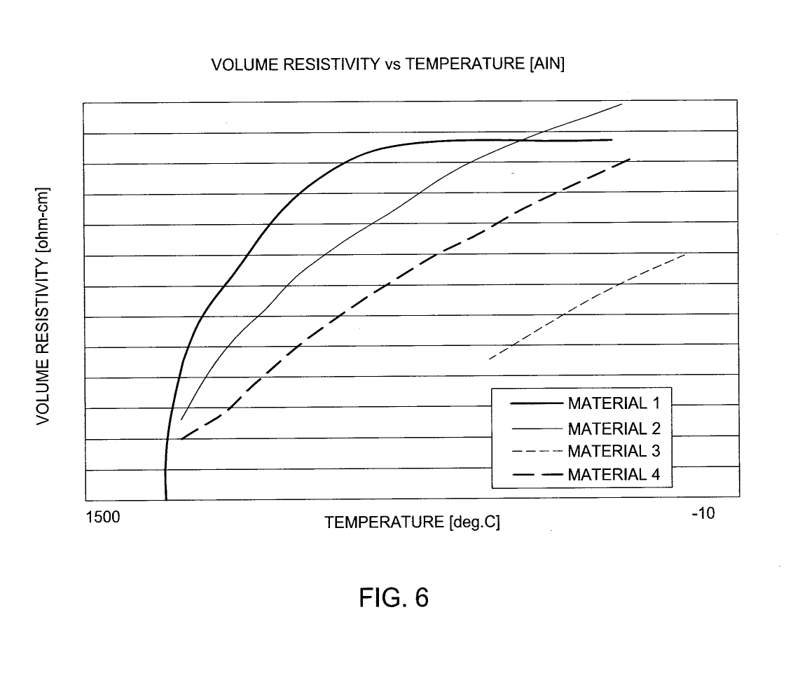

In Tables 1 and 2 provided below, we have provided examples of several specific grade aluminum nitride materials that can be used for ESC 220. Table 1 illustrates the composition of AlN dielectric materials. Table 2 illustrates mechanical properties for the AlN dielectric materials used in the ESC 220. FIG. 6 illustrates the electrical properties of the AlN dielectric materials. The volume resistivity is plotted against the temperature for a first, second, third and fourth material. Examples of AlN materials may be HA-50, HA-12, HA38, HA38L, HA-37, HA37L, HA37V, HA-35, HA40, HA20, HA45 or other similarly suitable material. The materials may have a volume resistivity ranging between about 1,e+00 ohm-cm to about 1.e+18 ohm-cm on an Y-axis and a temperature range between −10 degrees Celsius and about 1200 degrees Celsius on the X-axis. In an example implementation we can use the HA12 grade materials which can optimize chucking performance around 600 degree C.

TABLE 1

| | | Material | | | | | | |
|---|---|---|---|---|---|---|---|---|
| Property | | Aluminum Nitride | | | | | | |
| Purity | [atm %] | 99.0 | >99.9 | >99.9 | 99.8 | 99.0 | 99.0 | >99.9 |
| Bulk Density | [g/cc] | 3.33 | 3.26 | 3.26 | 3.30 | 3.27 | 3.33 | 3.26 |
| Thermal Conductivity | [W/m-K] | 170 | 90 | 90 | 100 | 80 | 170 | 90 |
| Liner Thermal Expansion | [×1e−6/deg-C.] | 5.7 | 5.7 | 5.4 | 5.0 | 5.6 | 5.5 | 5.5 |
| Coefficient (1000 deg. C.) | | | | | | | | |
| Flexural Strength @R.T. | [MPa] | 400 | 360 | 310 | 450 | 310 | 330 | 310 |
| Young's Modulus | [GPa] | 300 | 300 | 300 | 300 | 300 | 300 | 300 |
| Vickers Hardness | [Hv] | 987 | 1200 | 1050 | 1040 | — | 955 | — |

From the PECVD application point of view, high temperature leads to thin film quality advantages particularly in the specified operating temperature regime. For the ESC 220, it has been found that the thermal conductivity of 170 W/m-K of the grade HA12 AlN provides about a 5 degrees Celsius temperature range, or variation, at temperatures of about 650 degrees Celsius operation temperature.

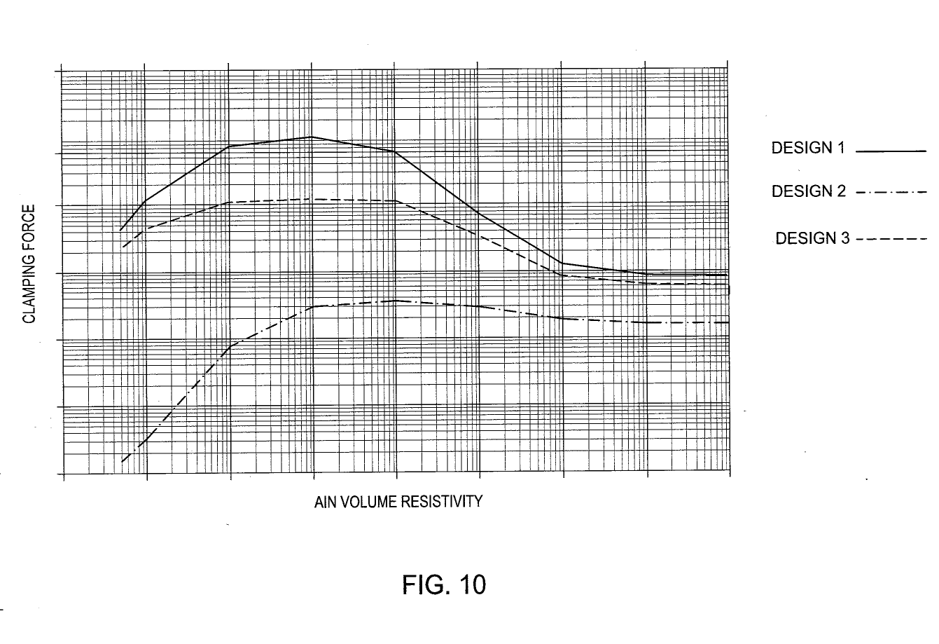

An appropriate chucking force is one that can clamp the substrate 540 in minimal or less than a few seconds of time, and sustain the clamping force until it is released. The appropriate chucking voltage or in effect a voltage-over-time sequence comes from the method, and may differ from recipe to recipe, or from one application to another. AlN volume resistivity also affects chucking force and the DC chucking power supply current. FIG. 10 is a graph illustrating how chucking force can be affected by several key parameters related to the geometry and material properties of the ESC. The graph shows three designs associated with, among other things, different ESC materials. For example, the chucking force variation against the AlN volume resistivity, contact gap height, and percentage of the contact area is based on calculation from the circuit model in FIG. 6.

It should be appreciated that the chucking force variation against the AlN volume resistivity shown in FIG. 10, is dependent on the contact gap height, and percentage of the contact area based on the chucking circuit 500 show described above relative to FIG. 5A. It is noticed that the ideal waveform of the contact gap voltage requires minimal rise and fall time, with a substantially flat portion in between where its value should approach a significant portion of the applied ESC supply voltage 552. Such requirements typically are not satisfied across the entire regime of the operating temperature if one uses the same grade of materials. This is due to the temperature dependent nature of the dielectric materials. FIG. 6 illustrates the volume resistivity for certain grades of the AlN materials varying by several orders of magnitude from the room temperature up to 750 degrees Celsius. Specifically, the data shows that resistivity goes down almost exponentially, when operating temperature increases linearly. Therefore, different configurations may be necessary to select the appropriate grade materials for a specified operating temperature regime.

Referring to FIG. 2 along with FIG. 5A, the surface charge built up at the top surface of the ESC 220 is a result of the charge migration due to finite conductivity of the semiconducting materials. The surface charge built up at the top surface brings closer the charges of the opposite polarity, effectively reducing the contact gap 221. The electrostatic chucking force is proportional to the square of the contact gap voltage 582, and is inversely proportional to the square of the contact gap height 521. Therefore, the charge migration across the contact gap 221 helps to increase the chucking force at a given ESC supply voltage 552. In other words, the material of the ESC 220 having a higher conductivity may exhibit higher chucking force compared to a conventional chuck having a lower conductivity. This phenomenon of charge migration was first described by Johnsen and Rahbek, often referred to as the J-R effect. In the high temperature regime, i.e., temperatures up to about 700° Celsius, the AlN dielectric materials exhibit high conductivity, or low resistivity, placing the disclosed ESC 220 implementation into a category of a J-R effect chuck. Contrary to the J-R category is the Columbic effect chuck where the dielectric materials are much less conductive, or even not conductive, requiring a higher ESC supply voltage 552 to reach the equivalent chucking force.

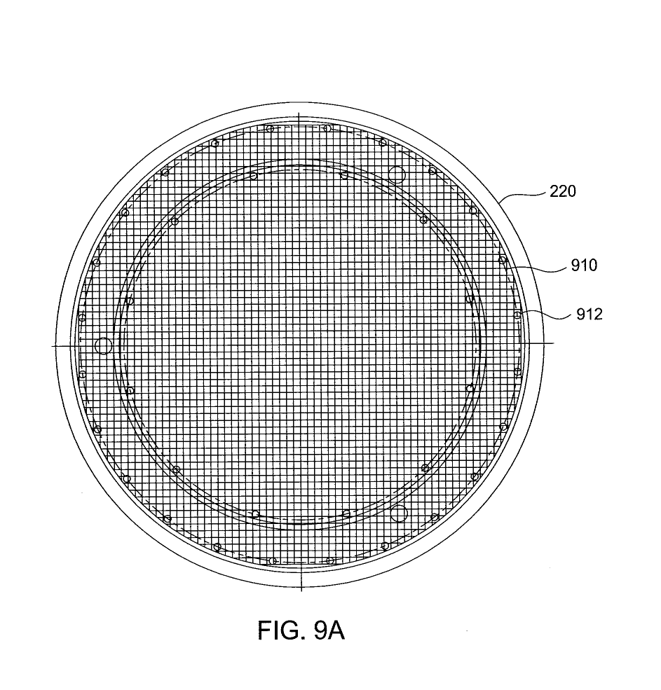

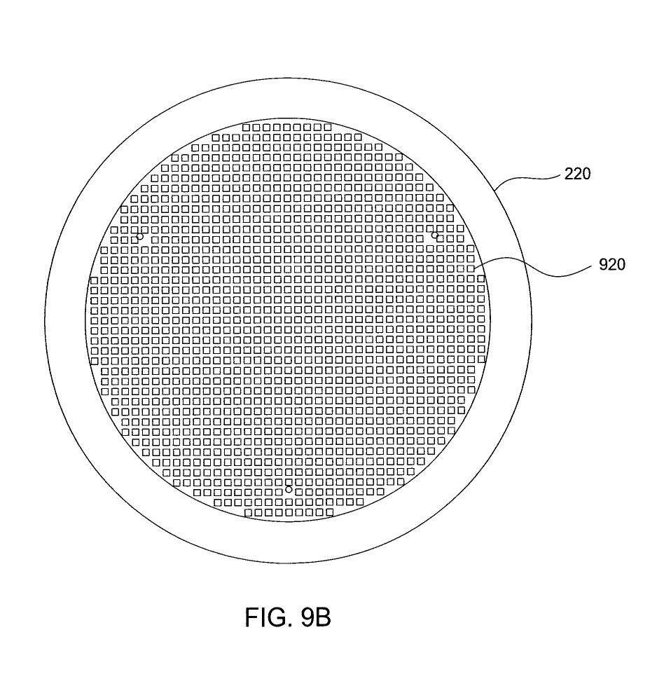

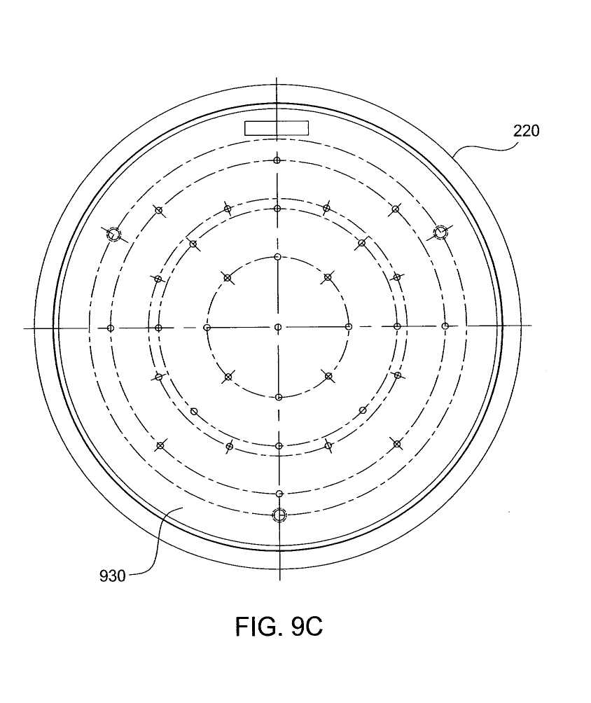

FIGS. 9A-9C illustrate examples of implementations for an AlN surface pattern suitable for forming a dense contact with the substrate. FIG. 9A is an example for an AlN surface pattern which makes a dense contact of about 64%, i.e., high contact area. FIG. 9B is an example of for an AlN surface pattern which makes a dense contact of about 30%, i.e., intermediate contact area. FIG. 9C is an example for an AlN surface pattern which makes a dense contact of about 0.3%, i.e., low contact area. The AlN surface pattern illustrated in FIGS. 9A through 9C are suitable for a 300 mm diameter substrate as well as a 450 mm diameter substrate. FIGS. 9A through 9C show several examples of optimizing surface contact against a particular type of process applications.

In FIG. 9A, square shaped islands with specified surface roughness are used to make contact with about 64% of the substrate back side area, in a uniform fashion, whereas a second example uses a sparse contact in a non-uniform fashion. Although the total chucking force is proportional to the effective contact area for a given clamping pressure, the contact area is not the only design consideration. Consideration to the thermal properties of the ESC 220 should be also taken in order to achieve desired temperature uniformity.

In FIG. 9B, a group of four erected objects, or tabs, are located just outside of the substrate edges, which are designed to contain the substrate within the tabs in case there is substrate movement prior to been chucked. Such substrate movement with respect to the ESC surface may be possible due to the phenomenon referred to as the thermal shock, or an instant thermal expansion of the substrate upon contact with the ESC surface at a different, or much higher temperature. An instant and partial mechanical expansion of the substrate dimension may lead to substantial substrate deformation, resulting in substrate displacement with respect to the ESC pedestal. This is not desirable if the substrate would remain displaced while the deposition process goes ahead upon it with in-consistent process results, or to the worst case substrate breakage.

Pre-heating the substrate to a temperature that is the same or substantially close to the ESC surface temperature can minimize the thermal shock. Disclosed method of preheating the substrate includes pre-heating prior to transferring into the process chamber and in-situ heating process using appropriate plasmas bombardments as the source of heat transfer. One example of implementing in-situ pre-heating is to create such a process step prior to deposition step using low RF power and inert gas at high pressure. Such inert gas species include He, Ar, Xe, etc. and the respective power level of around several hundreds of Watts to sustain a low density plasma. The details of such pre-heating step, or steps, may be optimized to contain combination of gas species, RF power, and pre-heat time to the effect that the substrate temperature after the pre-heating can reach that of the ESC pedestal temperature or with a sufficiently small temperature difference so that the thermal shock may be eliminated or minimized.

Alternative method of pre-heating the substrate to the ESC operating temperature may use a separate chamber where appropriate heating methods through contact heat transfer or radiation heat transfer may be employed to achieve the same effect. Such pre-heating chamber can be the existing load lock chamber for substrate transfer whereas a heating mechanism is implemented. We consider the design and implementation of pre-heating chambers as obvious to those who possess appropriate skills of arts, even though the details of any working implementation may not be described exactly in this specification.

Selection of the contact surface addresses an area of the ESC 220 that is very close to or in contact with the substrate, and affects chucking force and timing performance. The parameters may be selected to result in desirable chucking forces for any given application. These parameters include bulk ESC materials properties, surface contact area, any specific pattern of contact, e.g., such as shown in FIGS. 9A-9C, which contains the identical or non-identical contact islands, often referred to as mesa islands, the shape and height of each of the mesa island, and their collective distribution across the ESC surface, in either uniform or non-uniform number density with respect to part or all of the ESC surface, and the roughness Ra of the top contact surface finish, etc.

The contact surface optimization process may yield an ESC design best for one application requirement, or designs for a broad range of application requirements, depending upon the operating temperature, ESC voltage, ESC current, and the time to chuck or release. For example, one optimization process may target at minimum chucking voltage using maximum contact area, while another one may require minimizing the DC chucking current on the ESC power supply. The requirement of lowering chucking current may be desirable from the power supply packaging point of view, as it would require a small form factor power ESC supply that can be easily integrated into the ESC assembly. Additional advantage of maintaining low chucking current is to minimize excessive DC power imposed upon the ESC bulk materials so as to reduce excessive resistive heating during chucking, in case the DC resistive heating related to chucking is not considered as a factor affecting the overall temperature distribution on the ESC 220 surface. In other words, the mean and distribution of the ESC surface temperature may change, with or without the applied DC chucking power, leading to a drift in substrate temperature.

Excessive ESC current when all, or a significant part of the ESC current goes through the substrate to ground may potentially exceed a threshold to which it would induce electrical damage to the device structures resided on the substrate. Such electrical damage may include charging damage and or insulation layer breaking down. Among several methods to optimize the ESC current under high operating temperature to minimize potential damage is through the use of dielectric materials having higher resistivity.

The HA-50 grade bulk AlN dielectric material for the ESC 220 has a volume resistivity of 1E10 W-cm at 650 degrees Celsius compared to that of the HA-12 grade, at 1E8 W-cm. Therefore, HA-50 will exhibit lower ESC current than HA-12. The total ESC current for the HA-12 grade material may go to ground directly, through the bulk material to the heater elements, without going through the plasma return path. At a higher AlN resistivity, such as for HA-50 grade bulk AlN dielectric material, the ESC current will tend to go through the plasma to ground.

Another way of reducing the ESC current going to ground through the heater elements is to float the heater elements with respect to ground potential. This method can eliminate the portion of the ground current completely, regardless of the resistivity of the bulk dielectric materials. An example of implementing such DC isolation is shown in FIG. 5B. FIG. 5B illustrates a cucking circuit having an isolation transformer 206 for the ESC 220.

The ESC may have a bipolar power supply 620 along with a capacitor 622 on the ground path of the chucking electrode. A temperature controller 474 may be coupled to the ESC 220 by an optical link 610 that allows control signals to be optically communicated between the controller 474 and the ESC 220. A temperature probe 472 may be disposed in or around the ESC 220 for detecting the temperature.

The heaters 204 are powered by AC lines of 50 Hz or 60 Hz, through the isolation transformer 206 inserted in between the heater 204 and the AC lines L1. The heaters 204 of the ESC 220 are configured to provide an operating temperature of about 650 degrees Celsius. The temperature controller 474 may control the heaters 204 in the ESC 220 through the optical link 610 in response to the probe 472 providing the temperature of the ESC 220 to the temperature controller 474.

DC current leakage may be reduced by the isolation transformer 206 for the AC power lines L1. Additionally the ground path may be cut off from the temperature controller 474 by the optical link 610. Therefore, leak currents to the plasma can be reduced by using negative chucking polarity due to the ion current due to the ion current being much lower than the electron current in the plasma.

FIG. 5B illustrates a cucking circuit having an isolation transformer for the ESC. The transformer provides a method of isolation and is designed to withstand the maximum ESC voltage without breaking down, but allowing for no DC current across its primary and secondary transformer coil windings. In the meantime however, the 50 Hz or 60 Hz AC current may pass freely between the primary and the secondary coil windings of the transformer. In case of heater elements comprised of multiple zones, multiple transformers or a single transformer with multiple primary and, or secondary coil windings may be necessary to maintain DC isolation between the heater elements to ground.

Yet another example of reducing the ESC current is to generate a layer of high resistivity or insulating materials on the ESC pedestal surface which would cut off or significantly reduce the DC current leaking through the plasma to chamber ground. Such insulating layer exhibits a higher resistivity compared to the bulk dielectric materials at the operating temperature, with good adhesion to the bulk dielectric materials under the operating temperature as well as withstanding any possible thermal cycles, and needs to be free of voids or pinholes which may become a DC current path to ground. Such insulating layer may have to sustain the same or sufficient isolation conditions when subjected to the maximum DC chucking voltage with or without any possible superposition with voltages in higher frequencies, namely, the AC line voltage and RF voltages of a single or multiple RF frequencies. Such isolation layer may be manufactured into the pedestal permanently through qualified coating process, or may be generated in-situ prior to the deposition process starts, either once or repeatedly, inside of the chamber environment. In the case of in-situ deposition of a layer of DC insulation, the thickness, area of coverage, and film composition may be controlled to achieve sufficient isolation over a appropriate period of time, if such layer may ware or deteriorate over time. Typical film composition includes silicon nitride, silicon oxide, and other similar or different properties which can satisfy the same isolation requirement.

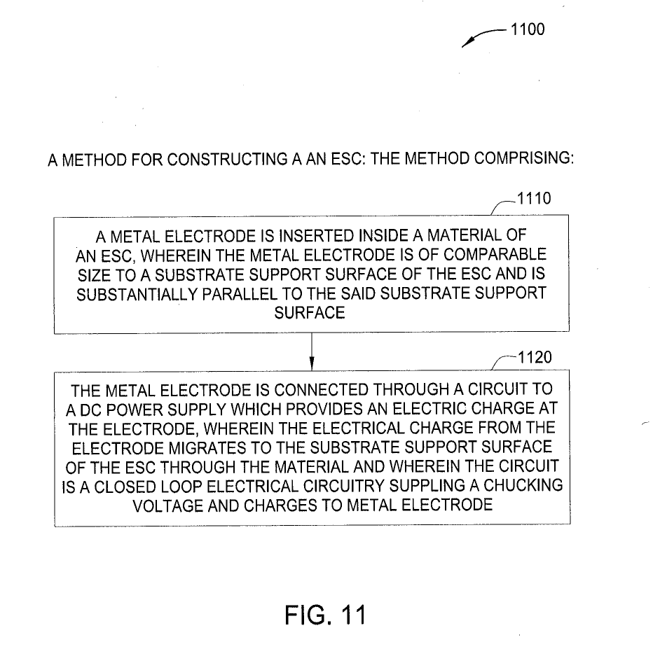

Turning now to FIG. 11, FIG. 11 illustrates a method for constructing the ESC 220. In a first operation 1110, a metal electrode is inserted inside a material of an ESC, wherein the metal electrode is of comparable size to a substrate support surface of the ESC and is substantially parallel to the substrate support surface. In a second operation 1120, the metal electrode is connected through a circuit to a DC power supply which provides an electric charge at the electrode, wherein the electrical charge from the electrode migrates to the substrate support surface of the ESC through the material and wherein the circuit is a closed loop electrical circuitry supplying a chucking voltage and charges to the metal electrode.

The metal heater elements are embedded inside the bulk dielectric material of the ESC so as to control the operating temperature as well as its uniformity across the chuck and the substrate. Such heater elements may be single or of multiple pieces of heater filaments made of tungsten, molybdenum or other resistive heater elements forming specific patterns. The position and layout of the heaters elements directly affect the operating temperature and the temperature distribution, or the temperature profile across the chuck surface. Such temperature profile may be substantially consistent over a period of time, or may be changed to a different yet desirable one by dynamically adjusting the power to each of the heater elements. Closed loop temperature control based on in-situ temperature sensors embedded inside the pedestal dielectric materials is used to maintain accurate operating temperature and the temperature gradient across the chuck and the substrate surface. It is an significant aspect to the PECVD application where the thin film quality such as their thickness and uniformity, stress, dielectric constant, and refractive indexes, etc., is closely related to the operating temperature during the film deposition.

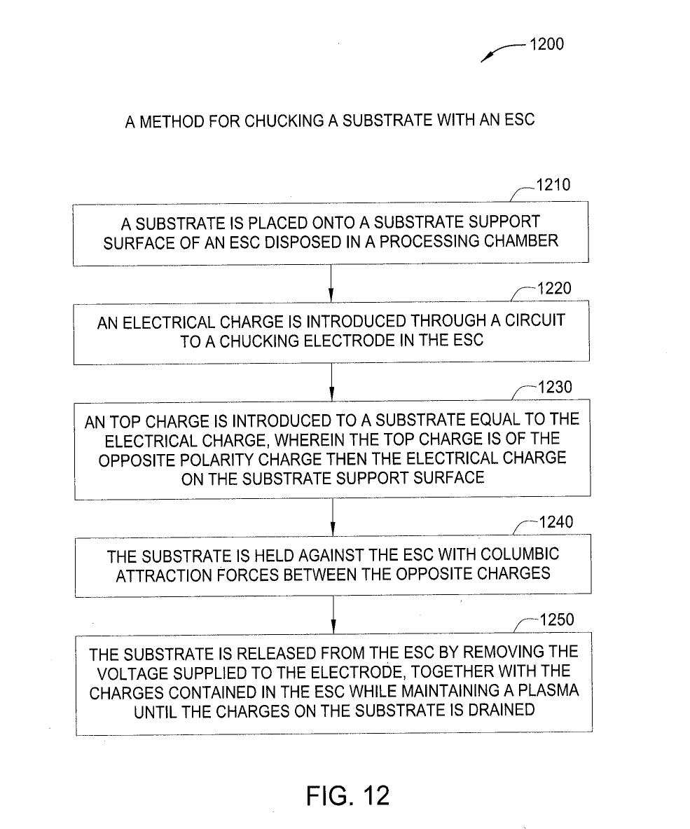

The operation of the ESC 220 will now briefly be discussed with respect to FIG. 12. FIG. 12 illustrates a method for chucking a substrate with an ESC. In a first operation 1210, a substrate is placed onto a substrate support surface of an ESC disposed in a processing chamber. In a second operation 1220, an electrical charge is introduced through a circuit to a chucking electrode in the ESC. In a third operation 1230, a top charge is introduced to a substrate equal to the electrical charge, wherein the top charge is of the opposite polarity charge then the electrical charge on the substrate support surface. In a fourth operation 1240, the substrate is held against the ESC with columbic attraction forces between the opposite charges. In a fifth operation 1250, the substrate is released from the ESC by removing the voltage supplied to the electrode, together with the charges contained in the ESC while maintaining a plasma until the charges on the substrate is drained.

In one embodiment, the timing controls for the ESC operating parameters are set to strike and sustain helium plasma with RF power before turning on the ESC voltage where the substrate may be heated to a high temperature due to helium plasma bombardment, leading reduced surface stress before chucking occurs. In another embodiment, the chucking method's runs different ESC voltages according to the recipe steps for optimal substrate results whereas, for example, a spike voltage may be used at the beginning of the chucking step to quickly chuck and flatten the bowing substrate while a lower ESC voltage is used for later process steps to maintain clamping force and to be ready for substrate release from a low chucking voltage.

Some additional non-limiting examples of the disclosed technology described herein may be described as follows:

### Example 1

A method and apparatus as described above for use to generate hard mask films formed of dielectric material for lithography applications in a semiconductor manufacturing process. The hard mask film may be deposited either on top of a bare silicon substrate or on top of a silicon substrate already bearing a thin film deposition layer of specified thickness and materials properties.

### Example 2

A method and apparatus as described above for use to generate on gate stack films with multiple, alternative layers of oxide and poly-silicon films, and with multiple, alternative layers of oxide and nitride films.

### Example 3

A method and apparatus as described in Examples 1 and 2 suitable for processing incoming substrates that are not flat or with specified bow, or may become not flat or exhibit specific bow due to accumulated residual stress during film growth. Such incoming substrate bow or accumulated substrate bow may be within 300 micro-meters from either tensile or compressive stress origins. The ideal bow specification of the gate stack is neutral bow or neutral stress after a number of alternative layers are deposited under high temperature.

### Example 4

A method and apparatus as described in the examples above suitable for processing incoming substrates at elevated temperatures as specified above with all thin film deposition occurring on the front or top side of the substrate, whereas there is no thin film depositions on the back side of the substrate despite the incoming substrate bow or accumulated substrate bow, or the lack of thereafter.

### Example 5

An high temperature ESC that is actively driven by one or multiple RF impedance matching circuit networks, a load impedance tuning circuit network, and a DC filter circuit network to support a capacitively coupled plasma for a PECVD process during the semiconductor manufacturing process flow.

### Example 6

The ESC of Example 5 may not be actively driven by one or multiple RF impedance matching circuit networks, but rather is held at or near the ground potential and acting as a ground path for actively driven stack of gas box and face plate by a separate RF impedance matching circuit network, or networks. However, the above ESC of Example 5 is driven by an adjustable or non-adjustable load impedance tuning circuit network, and a DC filter circuit network to support a capacitively coupled plasma for a PECVD process during the semiconductor manufacturing process flow.

### Example 7

The ESC of Example 5 or 6 having the RF impedance matching networks consisting of RF generators as the RF power source at the respective frequencies and variable tuning elements to achieve a desirable RF voltage, current, and coupled power at the substrate, where these RF voltage, current, and coupled plasma power are measured by embedded voltage and current sensors located inside or outside of the RF impedance matching networks, while at least one of sensors may be located at or near the substrate providing time domain signal of V(t), I(t), the phase difference between the sensors, and averaged values per RF cycle in terms of root mean square (RMS) values; and that the real power loss or the real coupled power can be derived from V(t)*I(t) averaged per RF cycle, or by the product of the RMS value of V(t) and I(t), and cos(Phase).

### Example 8

The above Example 5, 6 or 7, where the RF generators may change their respective frequencies to achieve desirable RF voltage, current, and coupled power at the substrate. The RF generators may provide non-continuous wave or pulsing operation where their amplitude may be modulated by a pulsing frequency and under a specified duty cycle. The RF generators may be programmed to exhibit either a random or consistent phase relationship with respect to each other.

### Example 9

The above DC filter circuit for the ESC of Example 5 or 6 comprising multiple inductive elements followed by several cascaded stages of π type, or other appropriate types of low pass filters having shunt capacitors and bridging inductors between them. The bridging inductor can be replaced by a parallel resonant circuit of an inductor and a capacitor to achieve high impedance at a particular resonant frequency. Such filter networks can exhibit both substantially high input impedance and substantially high attenuation at desired operating frequencies.

### Example 10

Apparatus and method of promptly clamping a substrate against a dielectric pedestal surface, and subsequently releasing the same substrate from the dielectric pedestal surface, where the substrate becomes substantially flat and is maintained substantially parallel with respect to the pedestal surface, regardless of whether the substrate is flat, or, it might have exhibited various degrees of compressive bow or tensile bow prior to being clamped by the pedestal.

### Example 11

The referred dielectric pedestal in Example 10 which operates in the range of 100 degrees Celsius to 700 degrees Celsius temperature that is desirable for semiconductor thin film deposition applications, and where the operating temperature is controlled in closed loop based upon the real time temperature measurements at any given time, or over a time period in which the operating temperature is substantially consistent, or it changes to follow a predefined course.

### Example 12

The dielectric pedestal operating in the range of 100 degrees Celsius to 700 degrees Celsius temperature range, where its temperature variation across the surface of the pedestal is substantially small, and in one example is less than several percent with respect to the mean operating temperature.

### Example 13

The dielectric pedestal operating in the range of 100 degrees Celsius to 700 degrees Celsius, where it incorporates embedded conductive electrode forming closed loop electrical circuitry in order to provide opposite charge polarity between the substrate back side and the pedestal top surface, and the closed loop may include a plasma sustained between the substrate and the conductive walls that contain the pedestal itself as well as other supporting parts.

### Example 14

The dielectric pedestal operating in the range of 100 degrees Celsius to 700 degrees Celsius, where it comprises of bulk dielectric materials of the appropriate thermal, mechanical, and electrical properties as those specified in above, and where the dielectric materials comprises of primarily Aluminum Nitride sintered under greater than 1000 degrees Celsius, forming a dense body of the pedestal of predefined geometry, and where the pedestal body may be further machined and polished comply with the predefined geometry and surface conditions. In particular to the electrical properties, the volume resistivity of the dielectric materials shall be controlled to fall in the range of 1E7 W-cm to 1E10 W-cm, depending upon their operating temperature, whereby such low level of the volume resistivity enables electrical charge migration from the embedded chucking electrode towards the top surface of the pedestal whereby such surface charge may induce the same amount of, but opposite polarity charge on the back side of the substrate. The opposite polarity charge can be sustained against discharging so as to generate continuous Coulombic attraction force that would clamp the substrate against the pedestal. Such regime of ESC operation is typically referred to as the Johnsen-Rahbek electrostatic chuck in prior arts which operate in a considerably lower temperature regime compared to the current invention. The novel Johnsen-Rahbek electrostatic chuck which operates under a much higher temperature, and in a much wider temperature range as compared to prior arts.

### Example 15

The dielectric pedestal in Example 10, operating in the range of 100 degrees Celsius to 700 degrees Celsius, wherein the dielectric pedestal incorporates embedded heater elements forming a specific pattern, or several specific patterns, which occupy different zones inside the body of the pedestal. These heater elements are powered with one or multiple DC power supplies or powered directly using the AC lines.

### Example 16

The dielectric pedestal in Example 15 operating in the range of 100 degrees Celsius to 700 degrees Celsius, where dielectric pedestal incorporates a network of electrical protection circuitry against potential harm due to radio frequency and lower frequency voltage and current that may present near or coupled from elsewhere to the pedestal. The protection circuitry may consist of fuses, switches, discharge paths to ground, current limiting devices, voltage limiting devices, and filtering devices to achieve sufficient attenuation of any potentially harmful voltage and current which may be distributed within one frequency exclusively, or spread across a broad frequency spectrum from DC, AC line frequencies, RF frequencies, up to the VHF frequencies.

### Example 17

The network of the electrical protection circuitry in Example 16 comprises of, but not limited to the below listed circuit topologies in p, L, and other relevant, equivalent or appropriate combinations of topologies, their input impedance, bandwidth, cut-off frequencies if any, their frequency response curves, and the degree of attenuation, etc.

### Example 18

The dielectric pedestal in Example 10 where the surface of the dielectric pedestal may contain fine features forming a uniform, or non-uniform, pattern upon clamping, and where the pattern may present to the back side of the substrate as a full percentage or partial percentage of the entire area of the back side of the substrate. The contacting surface of the pattern may exhibit micro roughness as a result of machining and polishing, and may contain a coating of substantially the same material as the pedestal, or different materials, of the appropriate thickness.

### Example 19

The dielectric pedestal in Example 10 where the surface of the dielectric pedestal may contain features in the form of distinct islands, or mesa structures whose top surface makes contact with the substrate back side, with either identical or different shapes of the islands, and distributed in either uniform density or non-uniform density across the ESC surface. The surface may also contain features whose top surface is not in contact with the substrate during processing, and may erect to a comparable or higher than the substrate level. The latter features described above may serve no purposes during substrate processing, or in case any substrate movement may occur prior to the substrate been chucked, serve as the substrate stops as needed. The number, shape, location, and materials composition of such substrate stops may not be limited to the disclosed implementation here in details, but may include features extensions into continuous, ring type of structures that may be detachable to the pedestal.

### Example 20

A method of operating the pedestal in Example 10 within the semiconductor manufacturing environment typically comprises of various chemistries under predefined pressure and temperature where the chucking electrode voltage, current, temperature are controlled over the processing time.

### Example 21

A method of using the pedestal in plasma enhanced chemical vapor deposition process.

### Example 22

The use of the method and apparatus in Example 10 in other thin film deposition and removal processes including, but not limited to, etch, physical vapor deposition, atomic layer deposition and etch, and others that employ both high temperature of operation and substrate clamping features.

The methods and apparatus disclosed above advantageously permit multiple layers, i.e., features such as gates, to be formed on the substrate at high temperatures for improved quality. The chucking techniques eliminate backside film deposition on bowed substrates during the film deposition process, which substantially increase lithography tool uptime by preventing contamination. The methods and apparatus disclosed herein are particularly suited for advanced photo films used for hard masks of dielectric materials for lithography applications in the semiconductor manufacturing process, as well as multiple film layers formed on a substrate, i.e. staircase films, used for gate stacks in memory devices. Thus, neutral bow or neutral stress bow specification of the gate stack is achievable after a number of alternative layers are deposited under high temperature.

While the foregoing is directed to embodiments of the present disclosure, other and further embodiments can be devised without departing from the basic scope thereof, and the scope thereof is determined by the claims that follow.

We claim:

1. A substrate support assembly comprising:
a substantially disk-shaped ceramic body having an upper surface, a cylindrical sidewall, and a lower surface, the upper surface configured to support a substrate thereon in a vacuum processing chamber, the cylindrical sidewall defining an outer diameter of the ceramic body, the lower surface disposed opposite the upper surface;
an electrode disposed in the ceramic body; and
a main circuit electrically connected to the electrode and configured to provide a chucking voltage thereto, the main circuit comprising:
a DC chucking circuit;
a first RF drive circuit; and
a second RF dive circuit, wherein the DC chucking circuit, the first RF drive circuit and the second RF drive circuit are electrically coupled together with the electrode.

2. The substrate support assembly of claim 1 wherein the main circuit further comprises:
a third RF load circuit.

3. The substrate support assembly of claim 1, wherein the first RF drive circuit comprises:
a high pass filter; and
a RF drive.

4. The substrate support assembly of claim 3, wherein the second RF drive circuit is operable to provide RF power at about 2 MHz and the first RF drive circuit is operable to provide RF power at about 13.56 MHz.

5. A processing chamber, comprising:
a body having walls and a lid enclosing an interior volume; and
a substrate support assembly disposed on the lid in the interior volume, the substrate support assembly comprising:
a substantially disk-shaped ceramic body having an upper surface, a cylindrical sidewall, and a lower surface, the upper surface configured to support a substrate thereon in a vacuum processing chamber, the cylindrical sidewall defining an outer diameter of the ceramic body, the lower surface disposed opposite the upper surface;
a bottom electrode disposed in the ceramic body; and
a main circuit electrically connected to the bottom electrode, the circuit comprising:
a DC chucking circuit;
a first RF drive circuit; and
a second RF dive circuit, wherein the DC chucking circuit, the first RF drive circuit and the second RF drive circuit are electrically coupled together with the electrode.

6. The processing chamber of claim 5, wherein the top electrode and the bottom electrode form a capacitively coupled plasma generator.

7. The processing chamber of claim 6 further comprising:
a first top circuit for driving the top electrode.

8. The processing chamber of claim 7 further comprising:
a second top circuit for driving the top electrode.

9. The processing chamber of claim 8, wherein the second top circuit is operable to provide RF power at about 400 KHz to the top electrode and the first top circuit is operable to provide RF power at about 27 MHz to the top electrode.

10. The processing chamber of claim 5, wherein the second RF drive circuit is operable to provide RF power at about 2 MHz and the first RF drive circuit is operable to provide RF power at about 13.56 MHz.

11. The processing chamber of claim 10, wherein the main circuit further comprises:
a third RF load circuit.

12. The processing chamber of claim 5, wherein the first RF drive circuit comprises:
a high pass filter; and
a RF drive.

13. A method for chucking a substrate with an ESC comprising:
placing a substrate on a substrate support surface of an ESC disposed in a processing chamber;
introducing an electrical charge through a circuit to a chucking electrode disposed in the ESC;
securing the substrate against the ESC with columbic attraction forces between the opposite charges; and
releasing the substrate from the ESC by removing the voltage supplied to the electrode, together with the charges contained in the ESC while maintaining a plasma until the charges on the substrate is drained.

14. The method of claim 13 further comprising;
forming a common ground between the ESC and a wall of the processing chamber through a plasma.

15. The method of claim 13 further comprising;
inducing surface charges on the bottom of the substrate from a contact connection between the top of the substrate to the other end of the DC power supply through a common ground connection that is a wall of the processing chamber.

16. The method of claim 15 further comprising;
striking and sustaining plasma between the substrate and the showerhead of the processing chamber to form the electric current loop.

17. The method of claim 13 wherein forming the ESC comprises;
inserting a metal electrode inside a bulk material of an ESC, wherein the metal electrode is of comparable size to a substrate support surface of the ESC and is substantially parallel to the substrate support surface; and
connecting the metal electrode is connected through a circuit to a DC power supply which provides an electric charge at the electrode, wherein the electrical charge from the electrode migrates to the substrate support surface of the ESC through the material and wherein the circuit is a closed loop electrical circuitry configured to supply a chucking voltage and charges to the metal electrode

18. The method of claim 17 wherein the bulk material is formed from aluminum nitride.

19. The method of claim 17 wherein the chucking electrode is formed from a single piece of material.

20. The method of claim 17 further comprising:
forming the chucking electrode from multiple electrodes configured to independently connected to different voltages.
